(19) United States
(12) Patent Application Publication
(10) Pub. No.: US 2004/0173891 A1
(43) Pub. Date: Sep. 9, 2004

(54) Intermediate board, intermediate board with a semiconductor device, substrate board with an intermediate board, structural member including a semiconductor device, an intermediate board and a substrate board, and method of producing an intermediate board

(75) Inventors: Ryuji Imai, Nagoya-shi (JP); Masao Kuroda, Inuyama-shi (JP); Yasuhiro Sugimoto, Konan-shi (JP)

Correspondence Address: SUGHRUE MION, PLLC, 2100 PENNSYLVANIA AVENUE, N.W., SUITE 800, WASHINGTON, DC, 20037, US

(73) Assignee: NGK SPARK PLUG CO., LTD.

(21) Appl. No.: 10/802,782

(22) Filed: Mar. 18, 2004

(30) Foreign Application Priority Data
Mar. 19, 2003 (JP) P.2003-076535
Mar. 7, 2003 (JP) P.2003-129127
Feb. 20, 2004 (JP) P.2004-045495

(51) Int. Cl. H01L 23/02

(52) U.S. Cl. 257/686

(57) ABSTRACT

An intermediate board comprising: an intermediate board body having first and second faces wherein a semiconductor device is to be mounted on at least one of said first and second faces, said semiconductor device having a coefficient of thermal expansion that is equal to or larger than 2.0 ppm/° C. and smaller than 5.0 ppm/° C., and having surface mount terminals, said intermediate board body having a plurality of through holes through which said first and second faces communicate with each other, said intermediate board body containing an inorganic insulating material; and a plurality of conductor columns filling said through holes and containing a conductive metal, said conductor columns being to be connected with said surface mount terminals.

### FIELD OF THE INVENTION

The present invention relates to an intermediate board, an intermediate board with a semiconductor device, a substrate board with an intermediate board, a structural member including a semiconductor device, an intermediate board, and a substrate board, and a method of producing an intermediate board.

### BACKGROUND OF THE INVENTION

Recently, various structural members are known in which a wiring board (such as an IC-chip mounting board or an IC package) on which an IC chip is mounted is not directly connected with a printed circuit board such as a motherboard, but the wiring board and the motherboard are connected with each other with interposing an intermediate board that is called an interposer, between the boards (for example, see JP-A-2000-208661 (FIG. 2(d), etc.)

Usually, an IC chip which is used in a structural member of this kind is formed by using a semiconductor material (for example, silicon) having a coefficient of thermal expansion of about 2.0 to 5.0 ppm/° C. By contrast, an intermediate board and a wiring board are often formed by using a resin material or the like having a coefficient of thermal expansion which is significantly larger than the above value. At present, however, a structural member in which an intermediate board is interposed between an IC chip and an IC-chip mounting board is not known.

### SUMMARY OF THE INVENTION

As recent advance in the integrated circuit technology, an IC chip operates at a higher speed. In accordance with this, there is a tendency to increase the size of an IC chip so as to form a larger number of arithmetic circuits. When the processing power of an IC chip is enhanced, however, the quantity of generated heat is expanded, and hence the influence of thermal stresses is gradually increased. In order to mount an IC chip onto an IC-chip mounting board, solder is usually used. When solder is cooled from the melt temperature to room temperature, thermal stresses due to difference in coefficient of thermal expansion between the IC chip and the IC-chip mounting board are generated.

When one side of the IC chip is larger than 10.0 mm, particularly, large thermal stresses act on the interface between the IC chip and the IC-chip mounting board, and the like, thereby causing the possibility that cracks or the like are produced in a chip bonding portion. When the IC chip has a thickness which is smaller than 1.0 mm, the strength is reduced, and hence there arises the possibility that cracks or the like are produced. As a result, such a structural member has a problem in that it cannot be provided with high reliability. When a low dielectric material (so-called low-K material) such as porous silica is employed as an interlayer insulation film, furthermore, it is expected that the IC chip is brittle and cracks are produced more easily.

The invention has been conducted in view of the above-discussed problems. It is an object of the invention to provide a structural member including a semiconductor device, an intermediate board, and a substrate board in which a portion bonded with the semiconductor device is highly reliable. It is another object of the invention to provide an intermediate board, an intermediate board with a semiconductor device, and a substrate board with an intermediate board which can be suitably used for realizing the excellent structural member. It is a further object of the invention to provide a production method which can efficiently produce the intermediate board at a low cost.

As means for solving the problems, a structural member is a structural member including a semiconductor device, an intermediate board, and a substrate board, comprising: a semiconductor device having a coefficient of thermal expansion that is equal to or larger than 2.0 ppm/° C. and smaller than 5.0 ppm/° C., and having surface mount terminals; a substrate board having a coefficient of thermal expansion that is equal to or larger than 5.0 ppm/° C., and having surface mount pads; and an intermediate board having: an intermediate board body of a substantially plate-like shape, the intermediate board body having a first face on which the semiconductor device is mounted, having a second face which is mounted on a surface of the substrate board, and having a plurality of through holes through which the first and second faces communicate with each other, the intermediate board body being made of an inorganic insulating material; and a plurality of conductor columns which are formed by filling the through holes with a conductive metal, and which are electrically connected with the surface mount terminals and the surface mount pads.

In the structural member, since the intermediate board body made of an inorganic insulating material and having a substantially plate-like shape is used, the difference in coefficient of thermal expansion with respect to the semiconductor device is small, and hence large thermal stresses do not act directly on the semiconductor device. Even when the semiconductor device is large in size and generates a large amount of heat, therefore, cracks and the like are hardly produced. As a result, the portion of the structural member where the semiconductor device is bonded can be provided with high reliability. The substrate board and the semiconductor device can be surely connected with each other through the conductor columns formed by a conductive metal which is filled into the through holes.

In order to realize such a structural member including a semiconductor device, an intermediate board, and a substrate board, suitably useful is an intermediate board comprising: an intermediate board body of a substantially plate-like shape, the intermediate board body having first and second faces on which a semiconductor device is to be mounted, the semiconductor device having a coefficient of thermal expansion that is equal to or larger than 2.0 ppm/° C. and smaller than 5.0 ppm/° C., and having surface mount terminals, the intermediate board body having a plurality of through holes through which the first and second faces communicate with each other, the intermediate board body being made of an inorganic insulating material; and a plurality of conductor columns which are formed by filling the through holes with a conductive metal, and which are to be electrically connected with the surface mount terminals. Also suitably useful is an intermediate board with a semiconductor device, comprising: a semiconductor device having a coefficient of thermal expansion that is equal to or larger than 2.0 ppm/° C. and smaller than 5.0 ppm° C., and having surface mount terminals; and an intermediate board having: an intermediate board body of a substantially plate-like shape, the intermediate board body having first and second faces on which the semiconductor device is mounted, the intermediate board body having a plurality of through holes through which the first and second faces communicate with each other, the intermediate board body being made of an inorganic insulating material; and a plurality of conductor columns which are formed by filling the through holes with a conductive metal, and which are electrically connected with the surface mount terminals. Moreover, also suitably useful is a substrate board with an intermediate board, comprising: a substrate board having a coefficient of thermal expansion that is equal to or larger than 5.0 ppm/° C., and having surface mount pads; and an intermediate board having: an intermediate board body of a substantially plate-like shape, the intermediate board body having a first face and a second face which is mounted on a surface of the substrate board, the intermediate board body having a plurality of through holes through which the first and second faces communicate with each other, the intermediate board body being made of an inorganic insulating material; and a plurality of conductor columns which are formed by filling the through holes with a conductive metal, and which are electrically connected with the surface mount pads.

As the semiconductor device, useful is a device having a coefficient of thermal expansion that is equal to or larger than 2.0 ppm/° C. and smaller than 5.0 ppm/° C., and having surface mount terminals. An example of such a semiconductor device is a semiconductor integrated circuit chip (IC chip) made of silicon having a coefficient of thermal expansion of about 2.6 ppm/° C. The surface mount terminal are terminals which are used for conducting electrical connections by means of surface connection. The surface connection is a technique in which pads or terminals are formed in a linear pattern or a lattice-like pattern (including a zigzag pattern) on flat faces of articles to be connected, and the articles are connected with each other. Although the size and shape of the semiconductor device are not particularly limited, it is preferable to set at least one side to be equal to or larger than 10.0 mm for the following reason. In the case of such a large semiconductor device, a large quantity of heat is easily generated, and the influence of thermal stresses is correspondingly increased. Therefore, the problems which are to be solved by the invention easily occur. Preferably, the semiconductor device has a porous layer in a surface portion because, in such a semiconductor device, the brittle porous layer easily cracks, and the problems which are to be solved by the invention easily occur.

As the substrate board, useful is a substrate board having a coefficient of thermal expansion that is equal to or larger than 5.0 ppm/° C., and having surface mount pads. An example of the substrate board is a substrate board on which semiconductor devices and other electronic components are to be mounted, or particularly a wiring board on which semiconductor devices and other electronic components are mounted and conductor circuits for electrically connecting the components are formed. The material forming the substrate board is not particularly limited as far as the condition that the coefficient of thermal expansion is equal to or larger than 5.0 ppm/° C. is satisfied. The material can be adequately selected in consideration of the cost, the workability, the insulation property, the mechanical strength, etc. Examples of the substrate board are a resin substrate board, a ceramic substrate board, and a metal substrate board.

Specific example of the resin substrate board are an EP resin (epoxy resin) substrate board, a PI resin (polyimide resin) substrate board, a BT (bismaleimide-triazine resin), substrate board, and a PPE resin (polyphenylene-ether resin). Alternatively, a substrate board made of a composite material formed by such a resin and glass fibers (glass woven fabric or glass nonwoven fabric) or organic fibers such as polyamide fibers may be used. Alternatively, a substrate board made of a resin-resin composite material which is formed by impregnating a three-dimensional network fluorine resin base material such as continuous porous PTFE with a thermosetting resin such as an epoxy resin may be used. Specific examples of the ceramic substrate board are an alumina substrate board, a beryllia substrate board, a glass ceramic substrate board, and a substrate board made of a low-temperature firing material such as crystallized glass may be used. Specific examples of the metal substrate board are a copper substrate board, a copper alloy substrate board, a substrate board made of a single metal other than copper, and a substrate board made of an alloy of metals other than copper.

The surface mount pads are terminal pads which are used for realizing electrical connections by means of surface connection. The surface mount pads are formed in, for example, a linear pattern or a lattice-like pattern (including a zigzag pattern).

As the material constituting the intermediate board body, an inorganic material typified by ceramic is used for the following reasons. Ceramic is generally smaller in coefficient of thermal expansion than a resin material, and hence suitably useful as a material of the intermediate board body. Furthermore, ceramic has preferable characteristics other than such a low coefficient of thermal expansion. Suitable examples of such ceramic are insulative engineering ceramic of an oxide (for example, alumina and beryllia), and insulative engineering ceramic of a nonoxide (for example, insulative engineering ceramic of a nitride typified by aluminum nitride, silicon nitride, and boron nitride). As the intermediate board body, useful is ceramic which is obtained by firing at a high temperature of 1,000° C. or higher. Alternatively, ceramic which is obtained by firing at a relatively low temperature that is lower than 1,000° C. (so-called low-temperature firing ceramic) may be used. A well-known example of such low-temperature firing ceramic is ceramic containing borosilicate glass, alumina, silica, etc.

The term “coefficient of thermal expansion” means a coefficient of thermal expansion in a direction (XY-direction) perpendicular to the thickness direction (Z-direction), and is a value which is measured by a TMA (thermomechanical analyzer) in a range of 0 to 200° C. The term “TMA” means thermomechanical analysis which is specified in, for example, JPCA-BU01. For example, the coefficient of thermal expansion of alumina is about 5.8 ppm/° C., that of aluminum nitride is about 4.4 ppm/° C., that of silicon nitride is about 3.0 ppm/° C., and that of low-temperature firing ceramic is about 5.5 ppm/° C.

Preferably, as described above, ceramic which is selected as the material constituting the intermediate board body has the insulation property for the following reason. In an intermediate board body not having the insulation property, an insulating layer must be previously formed before the formation of the conductor columns. By contrast, in an intermediate board body having the insulation property, such an insulating layer is not required. Therefore, the structure of the intermediate board can be prevented from being complicated, the production steps can be prevented from being increased, and hence the production cost of the whole of an apparatus can be lowered.

The intermediate board body may have either of a single-layer structure and a multi-layer structure. Preferably, the intermediate board body may have a single-layer structure because, in the case of a single-layer structure, the structure is relatively simple and can be easily produced, so that the cost reduction pan be readily attained. In the case of a single-layer structure, furthermore, there is no interface inside the structure, and hence cracks are hardly generated even when large thermal stress act on the structure.

The thickness of the intermediate board body is not particularly limited. In the case where alumina or low-temperature firing ceramic is selected, however, an intermediate board body having a thickness which is equal to or larger than 0.1 mm and equal to or smaller than 0.8 mm is preferably used. Particularly, an intermediate board body having a thickness which is equal to or larger than 0.3 mm and equal to or smaller than 0.8 mm is more preferably used. In such a thickness range, when the structural member is configured, relatively small thermal stresses acts on the semiconductor device bonding portion. This is advantageous to prevent the intermediate board body from warping, and also from cracking in the semiconductor device bonding portion. When the thickness of the intermediate board body is equal to or larger than 1.0 mm, the wiring resistance is increased, or the request for a reduced profile cannot be satisfied. Therefore, this is not preferable.

Also in the case where silicon nitride or the like is selected, the thickness of the intermediate board body is not particularly limited. However, the thickness is preferably equal to or larger than 0.1 mm and equal to or smaller than 0.7 mm, and more preferably equal to or larger than 0.1 mm and equal to or smaller than 0.3 mm.

Preferably, the intermediate board body has high rigidity (for example, a high Young's modulus) in addition to the above-mentioned low thermal expansion property. The rigidity, specifically Young's modulus of the intermediate board body is preferably higher than that of at least the semiconductor device, or 100 GPa or higher, or 200 GPa or higher, or particularly 300 GPa or higher. The reason of this is that, in the case where the intermediate board body is provided with high rigidity, even when large thermal stresses act on the intermediate board body, the intermediate board body can withstand the thermal stresses. Therefore, it is possible to prevent the intermediate board body from warping, and the semiconductor device bonding portion from cracking. Examples of a ceramic material which can satisfy the conditions are low-temperature firing ceramic (Young's modulus=125 GPa), alumina (Young's modulus=280 GPa), aluminum nitride (Young's modulus=350 GPa), and silicon nitride (Young's modulus=300 GPa). The term “Young's modulus” means a value measured by, for example, “Testing methods for elastic modulus of fine ceramics” specified in JIS R1602, and more specifically by the pulse echo method. In the pulse echo method, the dynamic elastic modulus is measured on the basis of the speed at which an ultrasonic pulse propagates through a test piece.

With respect to the flexural resistance which is another index indicating the rigidity of the intermediate board body, preferably, 200 MPa or more is preferable, and 300 MPa or more is particularly preferable. The reason of this is that, in the case where the intermediate board body is provided with high rigidity, even when large thermal stresses act on the intermediate board body, the intermediate board body can withstand the thermal stresses. Therefore, it is possible to prevent the intermediate board body from warping, and the semiconductor device bonding portion from cracking. Examples of a ceramic material which can satisfy the conditions are alumina (flexural resistance=350 MPa), aluminum nitride (flexural resistance=350 MPa), silicon nitride (flexural resistance=690 MPa), and low-temperature firing ceramic (flexural resistance=240 MPa). The term “flexural resistance” means a value measured by, for example, “Testing method for flexural strength of fine ceramics” specified in JIS R1601, and more specifically by the three-point bending strength test. In the three-point bending strength test, a test pieces is placed between two supporting points separated from each other by a given distance, a load is applied to one middle point between the two supporting points, and the value of the maximum bending stress when the test piece is broken is measured.

More preferably, the intermediate board body has a high heat dissipation property in addition to the above-mentioned low thermal expansion property and high rigidity. The term “high heat dissipation property” means that at least the heat dissipation property (for example, the coefficient of thermal conductivity) of the intermediate board body is higher than that of the substrate board. The reason of this is that, when a substrate board having a high heat dissipation property is used, heat generated by the semiconductor device can be rapidly transmitted so as to be dissipated, and hence thermal stresses can be moderated. Therefore, large thermal stresses do not act, so that the intermediate board body can be prevented from warping and the semiconductor device bonding portion can be prevented from cracking.

The intermediate board body has a plurality of through holes through which the first and second faces communicate with each other. Although the diameter of the through holes is not particularly limited, for example, the diameter is preferably equal to or smaller than 125 μm, and more preferably equal to or smaller than 100 μm (excluding 0 μm). Although the center-to-center distance between adjacent through holes is not particularly limited, for example, the minimum center-to-center distance is preferably equal to or smaller than 250 μm, and more preferably equal to or smaller than 200 μm (excluding 0 μm). When the diameter or the center-to-center distance is excessively large, there is the possibility that the intermediate board fails to sufficiently cope with finer patterning of a semiconductor device which is expected in the future. In other words, when the diameter or the center-to-center distance is set to an excessively large value, it is impossible to form many conductor columns in a restricted area. More preferably, the diameter of each through hole is equal to or smaller than 85 μm, and the minimum center-to-center distance between adjacent through holes is equal to or smaller than 150 μm (excluding 0 μm).

The intermediate board has a plurality of conductor columns. Each of the conductor columns is passed between the first and second faces so that one end is connected with the corresponding one of the surface mount terminals, and the other end is connected with the corresponding one of the surface mount pads. The conductor columns are formed by filling the through holes formed in the intermediate board body with a conductive metal. The conductive metal is not particularly limited, and may be, for example, one, or two or more metals selected from copper, gold, silver, platinum, palladium, nickel, tin, lead, titanium, tungsten, molybdenum, tantalum, and niobium. An example of a conductive metal configured by metals of two or more kinds is solder which is an alloy of tin and lead. Of course, as a conductive metal configured by metals of two or more kinds, lead-free solder (for example, Sn—Ag solder, Sn—Ag—Cu solder, Sn—Ag—Bi solder, Sn—Ag—Bi—Cu solder, Sn—Zn solder, or Sn—Zn—Bi solder) may be used. Examples of a specific technique of filling the through holes with a conductive metal are a technique in which a nonsolid material containing a conductive metal (for example, a conductive metal paste) is prepared and the holes are filled with the material by printing, and that in which conductive metal plating is applied.

In the case where the conductor columns are formed by filling the through holes in a ceramic-made intermediate board body with a conductive metal paste, a method of simultaneously sintering ceramic and a metal in the paste (the cofiring method), or that in which ceramic is first sintered, a paste is then loaded, and the metal in the paste is sintered (the post (second) firing method) may be employed. As a method of producing an intermediate board in which the cofiring method is employed, preferably useful is an intermediate board production method including a green body producing step of producing a ceramic green body having the through holes; a metal filling step of filling the through holes with the conductive metal; and a cofiring step of heating and sintering the ceramic green body and the conductive metal.

By contrast, as a method of producing an intermediate board in which the post firing method is employed, preferably useful is an intermediate board production method including: a firing step of firing a ceramic green body to produce the intermediate board body; a metalizing step of forming a metalization layer on the inner wall of each of the through holes in the intermediate board body; and a metal filling step of filling the through holes in which the metalization layer is formed, with the conductive metal. In the production method, a boring step of forming the through holes may be conducted before the firing step, or after the firing step.

As another method of producing an intermediate board in which the post firing method is employed, preferably useful is an intermediate board production method including: a first firing step of firing a ceramic green body to produce the intermediate board body; a metal filling step of filling the through holes of the intermediate board body with the conductive metal; and a second firing step of firing the filled conductive metal to form the conductor columns. In the production method, a boring step of forming the through holes may be conducted before the first firing step, or after the first firing step.

Either of the cofiring method and the post firing method is employed depending on, for example, the kind of the ceramic constituting the intermediate board. In the case where any one of the methods may be employed and the priority is placed on cost reduction, it is advantageous to employ the cofiring method. In the cofiring method, usually, a less number of production steps are required as compare with the post firing method, and intermediate board bodies can be produced in a correspondingly more efficient manner. In the case where the ceramic is high-temperature firing ceramic and the cofiring method is employed, the conductive metal constituting the conductor columns is preferably at least one refractory metal selected from tungsten, molybdenum, tantalum, and niobium. Even when such a metal encounters a high temperature of 1,000° C. or higher in a firing process, the metal is not oxidized nor evaporated, and can remain as a suitable sintered body in the through holes. In the case where the ceramic is low-temperature firing ceramic and the cofiring method is employed, the conductive metal constituting the conductor columns is not particularly necessary to be a refractory metal. In this case, therefore, a metal (such as copper, silver, or gold) which is lower in melting point than tungsten or the like, but which is excellent in conductivity may be selected as the conductive metal.

When the ceramic constituting the intermediate board is ceramic (for example, silicon nitride) which cannot be fired simultaneously with a metal material, the post firing method is inevitably employed. In this case, preferably, a metalization layer of some kind is formed on the inner wall of each of the through holes. When no metalization layer exists between the inner wall (i.e., the face made of the ceramic sintered body) of the through hole and the conductive metal and they are in direct contact with each other, it is sometimes difficult to provide them with a high adhesive strength. By contrast, when a metalization layer exists between the inner wall of the through hole and the conductive metal, it is easy to provide them with a high adhesive strength. Therefore, cracks are hardly generated in the interface between the inner wall of the through hole and the conductive metal, and the reliability of the ceramic-metal interface can be enhanced. By contrast, in the case where ceramic which can be fired simultaneously with a metal material is employed, a metalization layer is not always required. Therefore, such a metalization layer may not be formed.

As a technique of forming a metalization layer on the inner wall of the through hole, a well-known conventional technique can be employed. A specific example of the technique is a thin film formation method such as vapor deposition, CVD, PVD, sputtering, or ion plating. Among the methods, an isotropic thin film formation method such as vapor deposition or CVD is particularly suitable. Another example of the technique of forming a metalization layer is the activated metal method or the like. The metalization layer is formed by one, or two or more metals selected from copper, gold, silver, platinum, palladium, nickel, tin, lead, titanium, tungsten, molybdenum, tantalum, and niobium. The metal material used in the formation of the metalization layer may be identical with or different from the conductive metal constituting the conductor columns.

In the intermediate board body, preferably, a bump is formed on a surface of at least one of end portions of each of the conductor columns which are exposed from corresponding one of the through holes. In this case, it is preferable to form the bump on both the sides of the first and second faces for the following reason. In the case where the surface mount terminals or the surface mount pads are flat, when bumps are formed on the end portions of the conductor columns, the conductor columns can be easily connected with the surface mount terminals or the surface mount pads. The bumps may be solder bumps which are formed by printing a known solder material onto the end faces of the conductor columns and then conducting a reflow process. In the connection between the conductor columns and the surface mount terminals, or that between the conductor columns and the surface mount pads, for example, a technique may be employed in which, in the state where their end faces are opposed to each other, they are connected with each other by using a known conductive material such as solder or a conductive resin.

One or more electronic components and devices other than a semiconductor device may be disposed on the first and second faces of the intermediate board body. Specific examples of such electronic components are a chip transistor, a chip diode, a chip resistor, a chip capacitor, and a chip coil. These electronic components may be active components or passive components. Specific examples of such devices are a thin film transistor, a thin film diode, a thin film resistor, a thin film capacitor, and a thin film coil. These devices may be active devices or passive devices. A wiring layer for connecting the electronic components, connecting the devices, or connecting the electronic components, the devices, and the conductor columns may be formed on the first and second faces of the intermediate board body. Such a wiring layer may be formed inside the intermediate board body. In the case of an intermediate board body comprising a chip capacitor or a thin film capacitor, for example, the resistance and the inductance can be lowered, and hence a structural member of high performance can be easily realized.

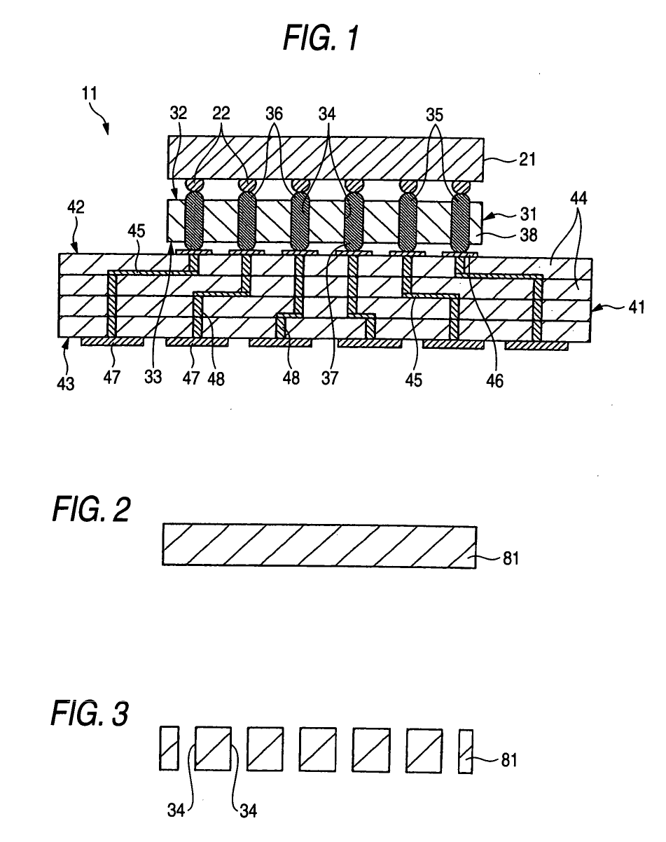

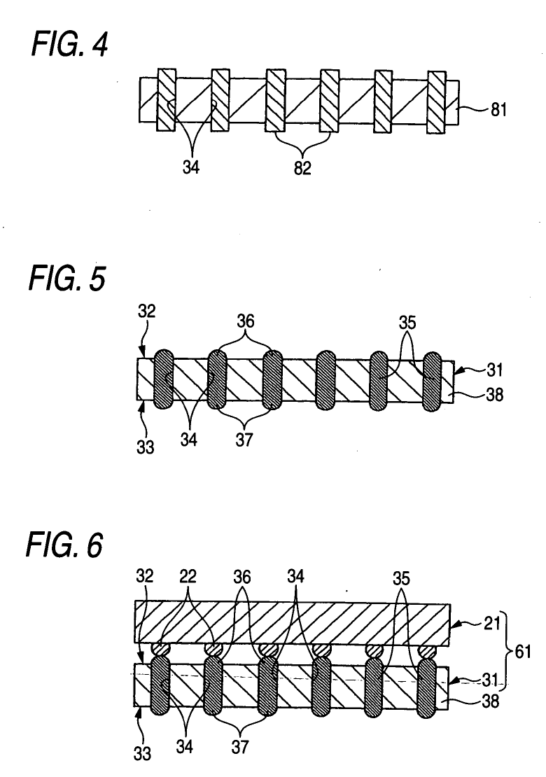

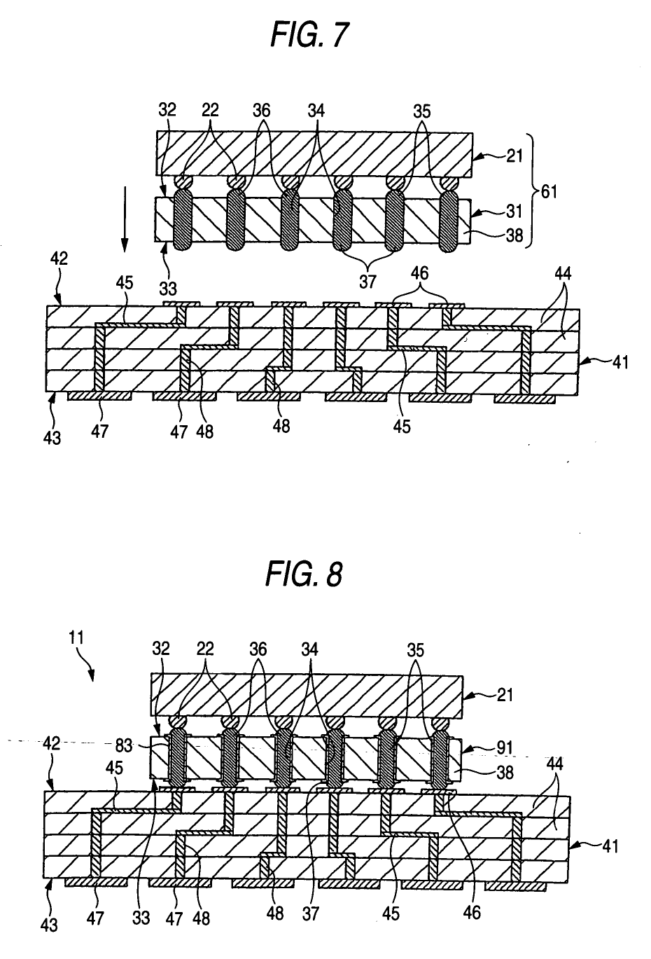

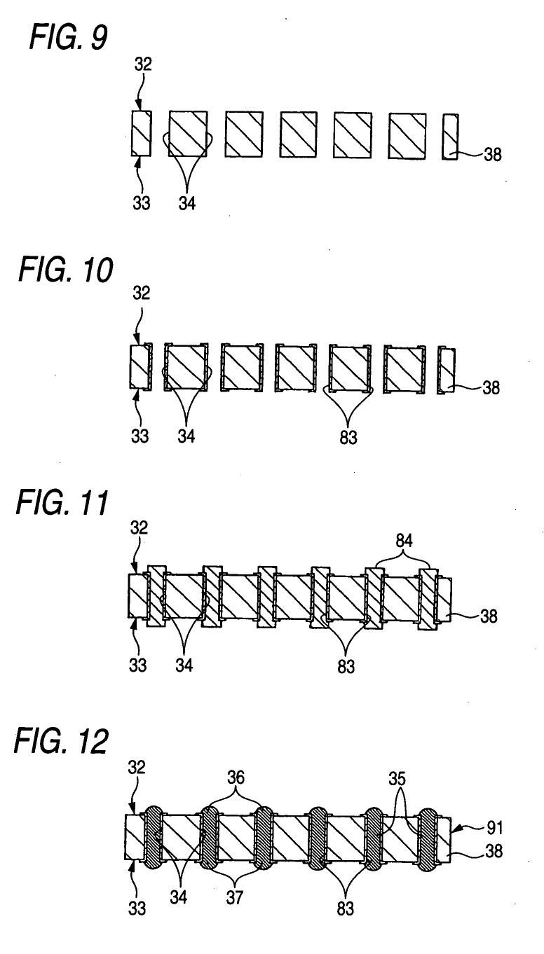

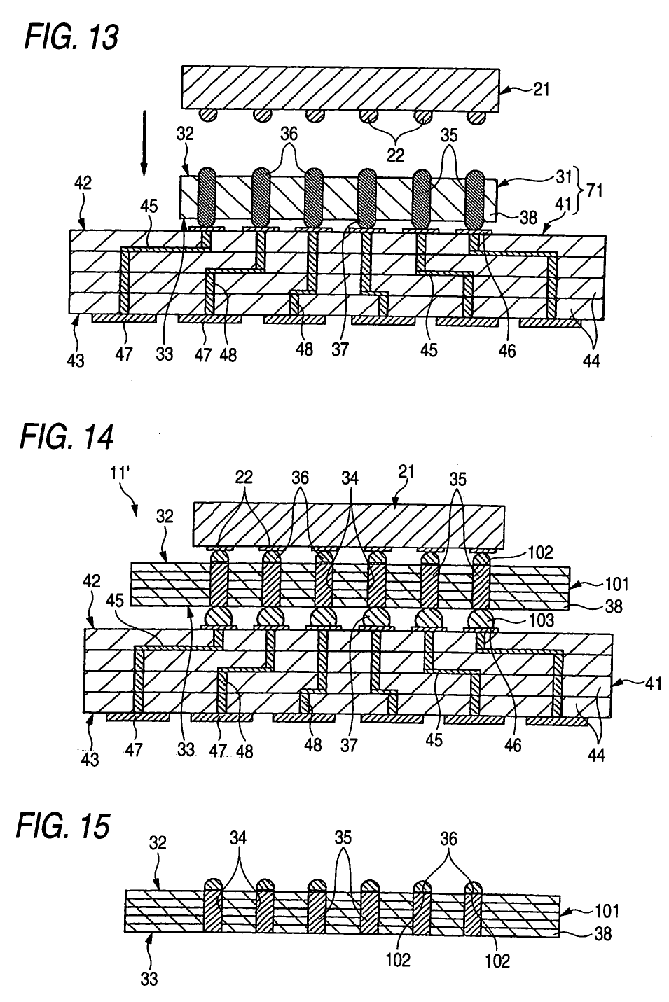

### BRIEF DESCRIPTION OF THE DRAWINGS

[FIG. 1] FIG. 1 is a schematic section view showing a semiconductor package (structural member) of a first embodiment including an IC chip (semiconductor device), an interposer (intermediate board), and a wiring board (substrate board).

[FIG. 2] FIG. 2 is a schematic section view illustrating a production process of the interposer of the first embodiment.

[FIG. 3] FIG. 3 is a schematic section view illustrating the production process of the interposer of the first embodiment.

[FIG. 4] FIG. 4 is a schematic section view illustrating the production process of the interposer of the first embodiment.

[FIG. 5] FIG. 5 is a schematic section view showing the completed interposer of the first embodiment.

[FIG. 6] FIG. 6 is a schematic section view showing an interposer with an IC chip (intermediate board with a semiconductor device) constituting the semiconductor package of the first embodiment.

[FIG. 7] FIG. 7 is a schematic section view showing a state where the interposer with an IC chip of the first embodiment is mounted on the wiring board.

[FIG. 8] FIG. 8 is a schematic section view showing a modification of the semiconductor package (structural member) of the first embodiment.

[FIG. 9] FIG. 9 is a schematic section view illustrating a production process of the interposer of the modification.

[FIG. 10] FIG. 10 is a schematic section view illustrating the production process of the interposer of the modification.

[FIG. 11] FIG. 11 is a schematic section view illustrating the production process of the interposer of the modification.

[FIG. 12] FIG. 12 is a schematic section view showing the completed interposer of the modification.

[FIG. 13] FIG. 13 is a schematic section view showing a state where an IC chip is mounted on a wiring board with an interposer. (substrate board with an intermediate board) in another modification of the first embodiment.

[FIG. 14] FIG. 14 is a schematic section view showing a semiconductor package (structural member) of a second embodiment including an IC chip (semiconductor device), an interposer (intermediate board), and a wiring board (substrate board).

[FIG. 15] FIG. 15 is a schematic section view showing the interposer of the second embodiment.

[Description of Reference Numerals and Signs]

11 . . . semiconductor package serving as structural member including semiconductor device, intermediate board, and substrate board

21 . . . IC chip serving as semiconductor device

22 . . . surface mount terminal

31, 91, 101 . . . interposer serving as intermediate board

32 . . . first face (of intermediate board)

33 . . . second face (of intermediate board)

34 . . . via serving as through hole

35 . . . conductor column

38 . . . interposer body serving as intermediate board body

41 . . . wiring board serving as substrate board

46 . . . surface mount pad

61 . . . interposer with IC chip serving as semiconductor device with semiconductor device

71 . . . wiring board with interposer serving as substrate board with intermediate board

### DETAILED DESCRIPTION OF THE INVENTION

[First Embodiment]

Hereinafter, a first embodiment in which the invention is embodied will be described in detail with reference to FIGS. 1 to 7.

FIG. 1 is a schematic section view showing a semiconductor package (structural member) 11 of the embodiment comprising an IC chip (semiconductor device) 21, an interposer (intermediate board) 31, and a wiring board (substrate board) 41. FIGS. 2, 3, and 4 are schematic section views illustrating the production process of the interposer 31. FIG. 5 is a schematic section view showing the completed interposer 31. FIG. 6 is a schematic section view showing an interposer 61 with an IC chip (intermediate board with a semiconductor device) constituting the semiconductor package 11. FIG. 7 is a schematic section view showing a state where the interposer 61 with an IC chip is mounted on the wiring board 41.

As shown in FIG. 1, the semiconductor package 11 is an LGA (Land Grid Array) which comprises the IC chip 21, the interposer 31, and the wiring board 41 as described above. The form of the semiconductor package 11 is not restricted to an LGA, and the semiconductor package may be a BGA (Ball Grid Array), a PGA (Pin Grid Array), or the like. The IC chip 21 functioning as an MPU has a rectangular flat plate-like shape of 10 mm square, and is made of silicon having a coefficient of thermal expansion of about 2.6 ppm/° C. An interlayer insulation film (not shown) made of porous silica which is a low-K material, and circuit devices (not shown) are formed in the lower surface layer of the IC chip 21. A plurality of bump-like surface mount terminals 22 are disposed in a lattice-like pattern on the lower face of the IC chip 21.

The wiring board 41 is a so-called multilayer wiring board which is formed by a flat plate-like member having an upper face 42 and a lower face 43, and which has plural resin insulating layers 44 and plural layers of conductor circuits 45. In the embodiment, specifically, the resin insulating layers 44 are formed by an insulating base material which is formed by impregnating glass cloth with an epoxy resin, and the conductor circuits 45 are formed by copper foil or copper plate layers. The thus configured wiring board 41 has a coefficient of thermal expansion which is equal to or larger than 13.0 ppm/° C. and equal to or smaller than 16.0 ppm/° C. A plurality of surface mount pads 46 for conducting electrical connections with the interposer 31 are formed in a lattice-like pattern on the upper face 42 of the wiring board 41. A plurality of surface mount pads 47 for conducting electrical connections with a motherboard which is not shown are formed in a lattice-like pattern on the lower face 43 of the wiring board 41. The surface mount pads 47 for connecting with the motherboard are formed in a larger area and at a wider pitch than the surface mount pads 46 for connecting with the interposer. Via hole conductors 48 are disposed in the resin insulating layers 44 so that the conductor circuits 45 of different layers, the surface mount pads 46, and the surface mount pads 47 are electrically connected with one another through the via hole conductors 48. In addition to the interposer 61 with an IC chip shown in FIG. 7, chip capacitors, semiconductor devices, and other electronic components (all components are not shown) are mounted on the upper face 42 of the wiring board 41.

The interposer 31 comprises an interposer body 38 (intermediate board body) which has a rectangular flat plate-like shape, and which has an upper face 32 (first face) and a lower face 33 (second face). The interposer body 38 is formed by an alumina substrate having a single-layer structure. The alumina substrate has a coefficient of thermal expansion of about 5.8 ppm/° C., a Young's modulus of about 280 GPa, and a flexural resistance of about 350 MPa. Therefore, the coefficient of thermal expansion of the interposer body 38 is smaller than that of the wiring board 41, and larger than that of the IC chip 21. Namely, it can be said that the interposer 31 of the embodiment is lower in thermal expansion property than the wiring board 41. Since the Young's modulus of the alumina substrate is higher than the Young's modulus (186 GPa) of the IC chip 21 which is used in the embodiment, the interposer 31 of the embodiment has high rigidity. Alternatively, the interposer body 38 may be formed by a substrate of low-temperature firing ceramic.

In the interposer body 38 constituting the interposer 31, a plurality of vias 34 (through holes) which are passed between the upper face 32 and the lower face 33 are formed in a lattice-like pattern. The vias 34 positionally correspond to the surface mount pads 46 of the wiring board 41, respectively. Conductor columns 35 made of tungsten (W) are disposed in the vias 34, respectively. An upper face bump 36 having a substantially hemispherical shape is disposed on the upper end face of each of the conductor columns 35. The upper face bumps 36 protrude from the upper face 32, and are connected with the surface mount terminals 22 of the IC chip 21, respectively. A lower face bump 37 having a substantially hemispherical shape is disposed on the lower end face of each of the conductor columns 35. The lower face bumps 37 protrude from the lower face 33, and are connected with the surface mount pads 46 of the wiring board 41, respectively. The upper face bumps 36 and/or the lower face bumps 37 may be solder bumps which are formed by printing a known solder material and then conducting a reflow process.

In the thus structured semiconductor package 11, therefore, the wiring board 41 and the IC chip 21 are electrically connected with each other through the conductor columns 35 of the interposer 31. Consequently, signals can be input and output between the wiring board 41 and the IC chip 21 via the interposer 31, and a power supply for operating the IC chip 21 as an MPU can be supplied via the interposer 31. In the case where the interposer body 38 is formed by a substrate of low-temperature firing ceramic, the conductor columns 35 are preferably formed by using silver (Ag) or copper (Cu) which is highly conductive. The interposer 31 having such conductor columns 35 is suitably used for enhancing the speed.

Hereinafter, a procedure for producing the semiconductor package 11 having the above-described structure will be described.

The interposer 31 is produced in, for example, the following procedure. First, an alumina green sheet 81 shown in FIG. 2 is produced by a well-known technique of forming a ceramic green sheet (green body producing step) such as a press molding. As shown in FIG. 3, the vias 34 (through holes) are opened in a lattice-like pattern at predetermined positions of the alumina green sheet 81. The vias 34 (through holes) are formed by, for example, a drilling process, a punching process, or a laser process. The formation of the vias 34 (through holes) may be conducted at the same time with as the process of molding the alumina green sheet 81. In any case, in the embodiment, the boring process is conducted in the stage of a green body, and hence the boring process can be conducted in a relatively easy manner and at a low cost as compared with a method in which a boring process is conducted in a stage of a sintered body. As shown in FIG. 4, tungsten paste 82 (paste containing a conductive metal) which is conventionally well known is then printed by using a screen printing apparatus or the like, and the vias 34 are filled with the tungsten paste 82 (metal filling step). The alumina green sheet 81 which has undergone the paste filling process is transported into a firing oven, and the alumina green sheet 81 and the tungsten paste 82 are heated to one thousand and several hundreds of ° C., whereby alumina and tungsten in the paste are simultaneously sintered (cofiring step). As a result, the interposer 31 shown in FIG. 5 is obtained. In each of the conductor columns 35 formed by the sintered tungsten paste 82, the upper and lower end faces are swollen into a substantially hemispherical shape by the function of surface tension, whereby the upper face bump 36 and the lower face bump 37 are formed. In the case where the conductor column 35 is swollen in few or small degree, a solder bump may be formed on at least one of the upper face 32 and the lower face 33 by printing a known solder material (for example, lead-free Sn/Ag solder) and conducting a reflow process.

Next, the IC chip 21 is placed on the upper face 32 of the completed interposer 31. At this time, the surface mount terminals 22 of the IC chip 21 are made positionally coincident with the upper face bump 36 of the interposer 31 respectively. Then, a heating process is applied to cause the upper face bumps 36 to reflow, whereby the upper face bumps 36 and the surface mount terminals 22 are bonded to each other. As a result, the interposer 61 with an IC chip shown in FIG. 6 is completed.

Next, the lower face bumps 37 of the interposer 31 are made positionally coincident with the surface mount pads 46 of the circuit board 41 (see FIG. 7), and the interposer 61 with an IC chip is placed on the circuit board 41. Known solder bumps (not shown) may be previously formed on the surfaces of the surface mount pads 46, respectively. Then, the lower face bumps 37 and the surface mount pads 46 are bonded to each other, respectively. Thereafter, the interfaces are sealed as required by an underfilling material (not shown), whereby the semiconductor package 11 shown in FIG. 1 is completed.

In order to evaluate the thus structured semiconductor package 11, a simulation test was conducted in the following manner. In the test, simulations were conducted in which the thickness of the interposer body 38 is set to several values (0 mm, 0.1 mm, 0.2 mm, 0.4 mm, 0.6 mm, and 0.8 mm), test samples are subjected to a heat cycle of 220 to 25° C., and the degree (MPa) of thermal stresses acting on a chip bonding portion is measured. In the test, the size of the IC chip 21 was set to a length of 12.0 mm×a width of 10.0 mm×a thickness of 0.7 mm, and that of the circuit board 41 was set to a length of 45.0 mm×a width of 45.0 mm. In the interposer body 38, solder bumps were formed on the upper face 32 and the lower face 33 of the interposer body 38 by lead-free solder of a composition of 95 Sn/5 Ag. Results of the test are listed below. In the list below, “0 mm comp. example)” means that an interposer is not used.

| Thickness of interposer | Degree of thermal | |
|---|---|---|
| body 38 | stress | Evaluation |
| 0 mm | 317 MPa | Bad |
| (comp. example) | | |
| 0.1 mm | 228 MPa | Good |
| 0.2 mm | 180 MPa | Good |
| 0.4 mm | 123 MPa | Excellent |
| 0.6 mm | 86 MPa | Excellent |
| 0.8 mm | 100 MPa | Excellent |

As apparent also from the results of the above simulation test, it was proved that, when the thickness of the interposer body 38 is set to be equal to or larger than 0.1 mm and equal to or smaller than 0.8 mm (particularly, equal to or larger than 0.4 mm and equal to or smaller than 0.8 mm), thermal stresses acting on a chip bonding portion is surely reduced. Furthermore, it was expected that, when the thickness is equal to or larger than 1.0 mm, the wiring resistance is increased, or the request for a reduced profile cannot be satisfied.

Therefore, the embodiment can attain the following effects.

(1) The semiconductor package 11 (structural member) is configured by using the interposer body 38 made of alumina and having a substantially plate-like shape. Therefore, the difference in coefficient of thermal expansion between the interposer 31 and the IC chip 21 is small, and hence large thermal stresses do not act directly on the IC chip 21. Even when the IC chip 21 is large in size and generates a large amount of heat, therefore, cracks and the like are hardly produced in the interface between the IC chip 21 and the interposer 31. As a result, the chip bonding portion and the like can be provided with high reliability, and it is possible to realize the semiconductor package 11 with excellent reliability and durability. Furthermore, alumina is an economical ceramic material as compared with silicon nitride and the like, and tungsten is a conductive metal material which is commonly used. When these materials are combinedly used, therefore, it is possible to realize the interposer 31 and the semiconductor package 11 which are relatively economical.

(2) In the embodiment, as the method of sintering the metal contained in the paste 82, the cofiring method is employed. Therefore, a relatively less number of production steps are required, and the interposer 31 can be correspondingly produced in a more efficient manner at a lower cost.

(3) The first embodiment may be modified in the following manner. As shown in a modification shown in FIG. 8, for example, the semiconductor package 11 is configured by using an interposer 91 (intermediate board) in which a metalization layer 83 is formed on the inner wall of each of the vias 34. The interposer 91 is produced in, for example, the following procedure. First, an alumina green sheet 81 is produced, and a boring process is previously conducted at predetermined positions. The resulting green sheet is then fired to produce an interposer body 38 shown in FIG. 9 (firing step). Next, vacuum deposition of tungsten is conducted in a state where a mask (not shown) is disposed, to form the metalization layer 83 of a thickness of 1 μm or smaller on the whole of the inner wall of each of the vias 34 as shown in FIG. 10 (metalizing step). Thereafter, as shown in FIG. 11, the vias 34 in which the metalization layer 83 is formed are filled with solder 84 which is a kind of conductive metal (metal filling step). For example, this step can be conducted by the following specific technique. A high-melting point solder ball of 90% Pb−10% Sn is placed in the upper end opening of each of the vias 34, and then heated to melt. As a result, the molten high-melting point solder downward moves by gravity to be poured into the via 34, and is fuse-bonded to the metalization layer 83 on the inner wall of the via 34. Furthermore, the upper and lower end faces of the conductor column 35 are swollen into a substantially hemispherical shape by the function of surface tension, to be formed as the upper face bump 36 and the lower face bump 37, respectively. As a result, the interposer 91 shown in FIG. 12 is completed.

(4) For example, the semiconductor package 11 (structural member) of the embodiment may be produced in the following manner. First, the interposer 31 is bonded to the upper face 42 of the circuit board 41 by soldering or the like, whereby a wiring board 71 with an interposer (substrate board with an intermediate board) is previously produced. Thereafter, the IC chip 21 is bonded to the upper face 32 of the wiring board 71 with an interposer, to form the desired semiconductor package 11 (see FIG. 13).

(5) A simulation test was conducted under the same conditions while the material of the interposer body 38 is changed from alumina to low-temperature firing ceramic, and that of the conductor columns 35 is changed from tungsten to copper. Similar results as those in the case of alumina were obtained. Specifically, results listed below were obtained. In the list below, “0 mm (comp. example)” means that an interposer is not used.

| Thickness of interposer | Degree of thermal | |
|---|---|---|
| body 38 | stress | Evaluation |
| 0 mm | 317 MPa | Bad |
| (comp. example) | | |
| 0.1 mm | 266 MPa | Good |
| 0.2 mm | 219 MPa | Good |
| 0.4 mm | 159 MPa | Excellent |
| 0.6 mm | 119 MPa | Excellent |
| 0.8 mm | 91 MPa | Excellent |

[Second Embodiment]

Hereinafter, a second embodiment in which the invention is embodied will be described in detail with reference to FIGS. 14 and 15. In the following, only points which are different from those of the first embodiment will be described. FIG. 14 is a schematic section view showing a semiconductor package (structural member) 11′ of the embodiment comprising an IC chip (semiconductor device) 21, an interposer (intermediate board) 101, and a wiring board (substrate board) 41. FIG. 15 is a schematic section view showing the interposer 101 of the embodiment.

As shown in FIGS. 14 and 15, the structure of the interposer 101 is slightly different from that of the first embodiment. In an interposer body 38 constituting the interposer 101 is formed by a silicon nitride substrate having a lamination structure in place of the alumina substrate having a single-layer structure. The silicon nitride has a coefficient of thermal expansion of about 3.0 ppm/° C., a Young's modulus of about 300 GPa, and a flexural resistance of about 690 MPa. The coefficient of thermal expansion, the Young's modulus, and the flexural resistance in the embodiment are higher than those in the first embodiment. In place of the conductor columns 35 made of tungsten, conductor columns 35 made of silver (Ag) are disposed in plural vias 34 of the interposer body 38, respectively. Therefore, the conductor columns 35 in the embodiment are lower in resistance than those in the first embodiment. Both the end faces of each of the conductor columns 35 are flat. A nickel-gold plate layer 102 is formed on the upper end face of each conductor column 35, and an upper end face bump 36 formed by substantially hemispherical solder is formed on the surface of the nickel-gold plate layer 102. By contrast, the nickel-gold plate layer 102 and a bump are not formed on the lower end face of each conductor column 35. Therefore, the lover end faces of the conductor columns 35 are connected with the surface mount pads 46 of the wiring board 41 via board solder bumps 103 disposed on the surface mount pads 46, respectively.

The interposer 101 of the embodiment can be produced by the post firing method. First, plural green sheets made of silicon nitride are produced, and a punching process is conducted at predetermined positions of each of the green sheets to form the vias 34 (boring step). Alternatively, the boring step may be conducted by a technique (for example, a drilling process or a laser process) other than a punching process. Next, the green sheets are laminated and then press-bonded together to be formed into a green sheet laminated member (laminating step). In the green sheet laminated member, then, unwanted parts (for example, outer peripheral portions) are adequately cut away to form a laminated member of a desired shape and size (external shape cutting step). The resulting green sheet laminated member is fired for a predetermined time under temperature conditions (1650 to 1950° C.) in which silicon nitride can be sintered, to be formed into the interposer body 38 having the vias 34 (first firing step). A metal filling step of filling the vias 34 with silver paste is then conducted by using a paste printing apparatus which is conventionally well known. Thereafter, the interposer body 38 is fired in a belt oven under conditions of 850° C. and 15 minutes (second firing step). As a result of this step, the silver paste in the vias 34 is sintered to be formed as the conductor columns 35. Next, the upper face 32 and the lower face 33 of the interposer body 38 are polished as required to flatten the end faces of the conductor columns 35. Thereafter, electroless nickel plating and electroless gold plating are sequentially conducted to form the nickel-gold plate layer 102 of a predetermined thickness on the upper end face of each conductor column 35. The nickel-gold plate layer 102 is formed in order to improve the adhesiveness between the upper end face bumps 36 which are formed in a subsequent step, and the conductor columns 35. Similarly, the nickel-gold plate layers 102 may be formed also on the lower end faces of the conductor columns 35. Next, the interposer body 38 is set to a paste printing apparatus, and solder paste containing lead-free solder of a composition of 95 Sn/5 Ag is printed in the state where a given metal mask is placed on the side of the upper face 32. After the solder printing step, the interposer body 38 is heated to a predetermined temperature to cause the solder to reflow. As a result of the reflow step, the upper face bumps 36 are formed on the nickel-gold plate layers 102, thereby completing the interposer 101 of FIG. 15. A metalizing step of forming a metalization layer on the inner wall face of each of the vias 34 may be conducted at a timing after the first firing step, and before the metal filling step.

In order to evaluate the thus structured semiconductor package 11′, a simulation test was conducted in the following manner. In the test, simulations were conducted in which the thickness of the interposer body 38 is set to several values (0 mm, 0.1 mm, 0.2 mm, and 0.4 mm), test samples are subjected to a heat cycle of 220 to 25° C., and the degree (MPa) of thermal stresses acting on a chip bonding portion is measured. In the test, the size of the IC chip 21 was set to a length of 12.0 mm×a width of 10.0 mm×a thickness of 0.7 mm, and that of the circuit board 41 was set to a length of 45.0 mm×a width of 45.0 mm. Results of the test are listed below. In the list below, “0 mm (comp. example)” means that an interposer is not used.

| Thickness of interposer | Degree of thermal | |
|---|---|---|
| body 38 | stress | Evaluation |
| 0 mm | 317 MPa | Bad |
| (comp. example) | | |
| 0.1 mm | 164 MPa | Excellent |
| 0.2 mm | 99 MPa | Excellent |
| 0.4 mm | 243 MPa | Good |

As apparent also from the results of the above simulation test, it was proved that, when the thickness of the interposer body 38 is set to be equal to or larger than 0.1 mm and equal to or smaller than 0.7 mm (particularly, equal to or larger than 0.1 mm and equal to or smaller than 0.3 mm), thermal stresses acting on a chip bonding portion is surely reduced. Furthermore, it was expected that, when the thickness is equal to or larger than 1.0 mm, the wiring resistance is increased, or the request for a reduced profile cannot be satisfied.

Therefore, the embodiment can attain the following effects.

(1) The semiconductor package 11′ (structural member) is configured by using the interposer body 38 made of silicon nitride and having a substantially plate-like shape. Therefore, the difference in coefficient of thermal expansion between the interposer 101 and the IC chip 21 is small, and hence large thermal stresses do not act directly on the IC chip 21. Even when the IC chip 21 is large in size and generates a large amount of heat, therefore, cracks and the like are hardly produced in the interface between the IC chip 21 and the interposer 101. As a result, the chip bonding portion and the like can be provided with high reliability, and it is possible to realize the semiconductor package 11 with excellent reliability and durability. Furthermore, the interposer 101 is configured by using silicon nitride in the insulator portion, and silver in the conductor portion. Therefore, the reliability and performance of the embodiment are higher than those of the first embodiment.

(2) In the embodiment, as the method of sintering the metal contained in the paste for forming the conductor columns 35, the post firing method is employed. Therefore, the degree of freedom in combination of the ceramic material and the metal material is larger than that in the first embodiment. Consequently, it is possible to select silver which cannot be fired simultaneously with silicon nitride. As a result, the conductor columns 35 of a low resistance can be formed. Namely, according to the production method of the embodiment, the interposer 101 of high reliability and high performance can be obtained in a relatively easy manner.

Next, technical concepts which can be grasped from the embodiments described above are listed below as preferred embodiments.

(1) An intermediate board comprising: an intermediate board body of a substantially plate-like shape, the intermediate board body having first and second faces on which a semiconductor device is to be mounted, the semiconductor device having a coefficient of thermal expansion that is equal to or larger than 2.0 ppm/° C. and smaller than 5.0 ppm/° C., and having surface mount terminals, the intermediate board body having a plurality of through holes through which the first and second faces communicate with each other, the intermediate board body being made of an inorganic insulating material; and a plurality of conductor columns which are formed by filling the through holes with a conductive metal, and which are to be electrically connected with the surface mount terminals.

(2) An intermediate board of (1) above, wherein the inorganic insulating material constituting the intermediate board body is low-temperature firing ceramic, and the conductive metal constituting the conductor columns is at least one of copper and silver.

(3) An intermediate board of (1) above, wherein a metalization layer is formed on the inner wall of each of the through holes.

(4) An intermediate board of (1) above, wherein the inorganic insulating material constituting the intermediate board body is ceramic which cannot be fired simultaneously with a metal material, and a metalization layer is formed on the inner wall of each of the through holes.

(5) An intermediate board of (1) above, wherein the intermediate board body is made of alumina or low-temperature firing ceramic, and the thickness of the intermediate board body is equal to or larger than 0.1 mm and equal to or smaller than 0.8 mm.

(6) An intermediate board of (1) above, wherein the intermediate board body is made of silicon nitride, and the thickness of the intermediate board body is equal to or larger than 0.1 mm and equal to or smaller than 0.7 mm.

(7) An intermediate board of (1) above, wherein at least one side of the semiconductor device is equal to or larger than 10.0 mm.

(8) An intermediate board of (1) above, wherein the intermediate board body is made of a material which is lower in coefficient of thermal expansion than the substrate board.

(9) An intermediate board of (1) above, wherein the intermediate board body is made of a material which is higher in rigidity than at least silicon.

(10) An intermediate board of (1) above, wherein the intermediate board body is made of a material having a Young's modulus of 100 GPa or higher.

(11) An intermediate board of (1) above, wherein the inorganic insulating material constituting the intermediate board body is ceramic, and the conductive metal constituting the conductor columns is at least one refractory metal selected from tungsten, molybdenum, tantalum, and niobium.

(12) A method of producing an intermediate board, the intermediate board comprising: an intermediate board body of a substantially plate-like shape, the intermediate board body having first and second faces on which a semiconductor device is to be mounted, the semiconductor device having a coefficient of thermal expansion that is equal to or larger than 2.0 ppm/° C. and smaller than 5.0 ppm/° C., and having surface mount terminals, the intermediate board body having a plurality of through holes through which the first and second faces communicate with each other, the intermediate board body being made of an inorganic insulating material; and a plurality of conductor columns which are formed by filling the through holes with a conductive metal, and which are to be electrically connected with the surface mount terminals, wherein the method includes: a firing step of firing a ceramic green body to produce the intermediate board body; a metalizing step of forming a metalization layer on the inner wall of each of the through holes in the intermediate board body; and a metal filling step of filling the through holes in which the metalization layer is formed, with the conductive metal.

This application is based on Japanese Patent application JP 2003-76535, filed Mar. 19, 2003, Japanese Patent application JP 2003-129127, filed May 7, 2003, and Japanese Patent application JP 2004-45495, filed Feb. 20, 2004, the entire contents of those are hereby incorporated by reference, the same as if set forth at length.

What is claimed is:

1. An intermediate board comprising:
an intermediate board body having first and second faces wherein a semiconductor device is to be mounted on at least one of said first and second faces, said semiconductor device having a coefficient of thermal expansion that is equal to or larger than 2.0 ppm/° C. and smaller than 5:0 ppm/° C., and having surface mount terminals, said intermediate board body having a plurality of through holes through which said first and second faces communicate with each other, said intermediate board body containing an inorganic insulating material; and
a plurality of conductor columns filling said through holes and containing a conductive metal, said conductor columns being to be connected with said surface mount terminals.

2. The intermediate board according to claim 1, wherein said through holes have a diameter which is equal to or smaller than 125 μm, and a minimum center-to-center distance between adjacent ones of said through holes is equal to or smaller than 250 μm.

3. The intermediate board according to claim 1, wherein said inorganic insulating material is low-temperature firing ceramic, and said conductive metal is at least one of copper and silver.

4. The intermediate board according to claim 1, wherein a metalization layer is formed on an inner wall of each of said through holes.

5. The intermediate board according to claim 1, wherein said inorganic insulating material is ceramic which cannot be fired simultaneously with a metal material, and a metalization layer is formed on an inner wall of each of said through holes.

6. The intermediate board according to claim 1, wherein said intermediate board body is made of alumina or low-temperature firing ceramic, and a thickness of said intermediate board body is 0.1 to 0.8 mm.

7. The intermediate board according to claim 1, wherein said intermediate board body is made of silicon nitride, and a thickness of said intermediate board body is 0.1 to 0.7 mm.

8. The intermediate board according to claim 1, wherein at least one side of said semiconductor device is equal to or larger than 10.0 mm.

9. The intermediate board according to claim 1, wherein said intermediate board body is made of a material which is higher in rigidity than at least silicon.

10. The intermediate board according to claim 1, wherein said intermediate board body is made of a material having a Young's modulus of 100 GPa or higher.

11. The intermediate board according to claim 1, wherein said inorganic insulating material is ceramic, and said conductive metal is at least one refractory metal selected from tungsten, molybdenum, tantalum, and niobium.

12. An intermediate board with a semiconductor device, comprising:
a semiconductor device having a coefficient of thermal expansion that is equal to or larger than 2.0 ppm/° C. and smaller than 5.0 ppm/° C., and having surface mount terminals; and
an intermediate board having: an intermediate board body having first and second faces wherein said semiconductor device is mounted on said first or second face, said intermediate board body having a plurality of through holes through which said first and second faces communicate with each other, said intermediate board body containing an inorganic insulating material; and a plurality of conductor columns filling said through holes and containing a conductive metal, said conductor columns being connected with said surface mount terminals.

13. The intermediate board with a semiconductor device according to claim 12, wherein said through holes have a diameter which is equal to or smaller than 125 μm, and a minimum center-to-center distance between adjacent ones of said through holes is equal to or smaller than 250 μm.

14. The intermediate board with a semiconductor device according to claim 12, wherein said inorganic insulating material is low-temperature firing ceramic, and said conductive metal is at least one of copper and silver.

15. The intermediate board with a semiconductor device according to claim 12, wherein a metalization layer is formed on an inner wall of each of said through holes.

16. The intermediate board with a semiconductor device according to claim 12, wherein said inorganic insulating material is ceramic which cannot be fired simultaneously with a metal material, and a metalization layer is formed on an inner wall of each of said through holes.

17. The intermediate board with a semiconductor device according to claim 12, wherein said intermediate board body is made of alumina or low-temperature firing ceramic, and a thickness of said intermediate board body is 0.1 to 0.8 mm.

18. The intermediate board with a semiconductor device according to claim 12, wherein said intermediate board body is made of silicon nitride, and a thickness of said intermediate board body is 0.1 to 0.7 mm.

19. The intermediate board with a semiconductor device according to claim 12, wherein at least one side of said semiconductor device is equal to or larger than 10.0 mm.

20. The intermediate board with a semiconductor device according to claim 12, wherein said intermediate board body is made of a material which is higher in rigidity than at least silicon.

21. The intermediate board with a semiconductor device according to claim 12, wherein said intermediate board body is made of a material having a Young's modulus of 100 GPa or higher.

22. The intermediate board with a semiconductor device according to claim 12, wherein said inorganic insulating material is ceramic, and said conductive metal is at least one refractory metal selected from tungsten, molybdenum, tantalum, and niobium.

23. A substrate board with an intermediate board, comprising:
a substrate board having a coefficient of thermal expansion that is equal to or larger than 5.0 ppm/° C., and having surface mount pads; and
an intermediate board having: an intermediate board body having a first face and a second face which is mounted on a surface of said substrate board, said intermediate board body having a plurality of through holes through which said first and second faces communicate with each other, said intermediate board body containing an inorganic insulating material; and a plurality of conductor columns filling said through holes and containing a conductive metal, said conductor columns being connected with said surface mount pads.

24. The intermediate board with a semiconductor device according to claim 23, wherein said intermediate board body is made of a material which is lower in coefficient of thermal expansion than said substrate board.

25. A structural member comprising:
a semiconductor device having a coefficient of thermal expansion that is equal to or larger than 2.0 ppm/° C. and smaller than 5.0 ppm/° C., and having surface mount terminals;
a substrate board having a coefficient of thermal expansion that is equal to or larger than 5.0 ppm/° C., and having surface mount pads; and
an intermediate board having: an intermediate board body having a first face on which said semiconductor device is mounted, having a second face which is mounted on a surface of said substrate board, and having a plurality of through holes through which said first and second faces communicate with each other, said intermediate board body containing an inorganic insulating material; and a plurality of conductor columns filling said through holes and containing a conductive metal, said conductor columns being connected with said surface mount terminals and said surface mount pads.

26. A method for producing an intermediate board, said intermediate board comprising: an intermediate board body having first and second faces wherein a semiconductor device is to be mounted on at least one of said first and second faces, said semiconductor device having a coefficient of thermal expansion that is equal to or larger than 2.0 ppm/° C. and smaller than 5.0 ppm/° C., and having surface mount terminals, said intermediate board body having a plurality of through holes through which said first and second faces communicate with each other, said intermediate board body containing an inorganic insulating material; and a plurality of conductor columns which filling said through holes and containing a conductive metal, said conductor columns being to be connected with said surface mount terminals, wherein
said method comprises:
a green body producing step of producing a ceramic green body having said through holes;
a metal filling step of filling said through holes with said conductive metal; and
a cofiring step of heating and sintering said ceramic green body and said conductive metal.

27. A method for producing an intermediate board, said intermediate board comprising: an intermediate board body having first and second faces wherein a semiconductor device is to be mounted on at least one of said first and second faces, said semiconductor device having a coefficient of thermal expansion that is equal to or larger than 2.0 ppm/° C. and smaller than 5.0 ppm/° C., and having surface mount terminals, said intermediate board body having a plurality of through holes through which said first and second faces communicate with each other, said intermediate board body containing an inorganic insulating material; and a plurality of conductor columns filling said through holes and containing a conductive metal, said conductor columns being to be connected with said surface mount terminals, wherein
said method comprises:
a first firing step of firing a ceramic green body to produce said intermediate board body;
a metal filling step of filling said through holes of said intermediate board body with said conductive metal; and
a second firing step of firing said filled conductive metal to form said conductor columns.
